(19) United States
(12) Patent Application Publication
(10) Pub. No.: US 2026/0362755 A1
(43) Pub. Date: Nov. 12, 2026

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Iuliana RADU, Hsinchu (TW); Hung-Li CHIANG, Hsinchu (TW); Hung-Chi HAN, Hsinchu (TW); Jer-Fu WANG, Hsinchu (TW); Goutham Arutchelvan, Hsinchu (TW); Chao-Ching CHENG, Hsinchu (TW)

(73) Assignee: Taiwan Semiconductor Manufacturing Company, Ltd., Hsinchu (TW)

(21) Appl. No.: 18/588,778

(22) Filed: Feb. 27, 2024

(51) Int. Cl. H10D 48/00; G06N 10/40; H10D 48/01; H10D 62/13; H10D 62/815; H10D 64/23; H10D 30/40

(52) U.S. Cl. CPC H10D 48/3835; G06N 10/40; H10D 48/031; H10D 62/151; H10D 62/8164; H10D 64/256; H10D 30/402

(57) ABSTRACT

A semiconductor device includes a substrate, a first quantum dot transistor structure and a second quantum dot transistor structure. The substrate has a first side and a second side opposite to the first side. The first quantum dot transistor structure is disposed on the first side. The second quantum dot transistor structure disposed on the second side for spin readout of a plurality of quantum dot qubits in the first quantum dot transistor structure.

### BACKGROUND

As the semiconductor industry introduces new generations of integrated circuits (IC) having higher performance and more functionality, the density of the elements forming the ICs increases, while the dimensions, sizes and spacing between components or elements are reduced. The semiconductor industry continues to improve the integration density of various electronic components (e.g., transistors, diodes, resistors, capacitors, etc.) by continual reductions in minimum feature size, which allow more components to be integrated into a given area.

However, in quantum dot transistors, spin readout is an important requirement for fault-tolerant quantum computing in spin qubits. Spin readout can be performed using a single-shot spin readout, which means that the spin state can be determined using a single iteration of the readout sequence. It is important to integrate the qubit readout capability into the existing control architecture of the semiconductor device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a semiconductor device in accordance with an embodiment of the present disclosure.

FIGS. 2A - 2C are schematic views for manufacturing a semiconductor device in accordance with an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

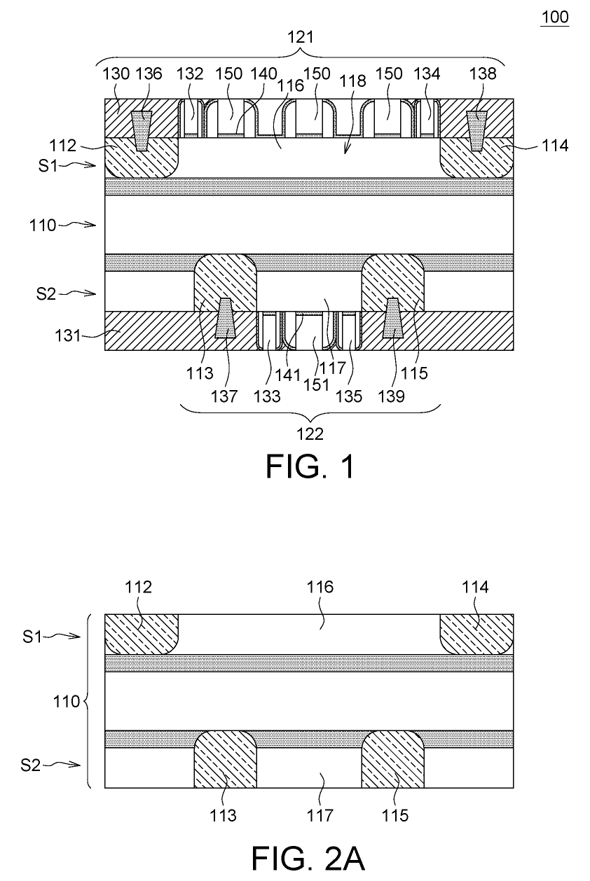

FIG. 1 is a cross-sectional view of a semiconductor device 100 in accordance with an embodiment of the present disclosure. The semiconductor device 100 includes a substrate 110, a source region 112, a drain region 114, a channel region 116, a pair of depletion gates (or barrier gates) 132 and 134, a plurality of accumulation gates 150, at least one charge sensor (i.e., 122) and a conductive resonator (not shown). The source region 112 and the drain region 114 are disposed in the substrate 110. The channel region 116 is disposed in the substrate 110 and between the source region 112 and the drain region 114. The depletion gates 132 and 134 are disposed over the channel region 116 and define a quantum dot qubit region 118 in the channel region 116 and between the depletion gates 132 and 134. In some embodiments, the quantum dot qubit region 118 allows only a single carrier (electron or hole) passing from an entrance of the quantum dot qubit region 118 (i.e., a region beneath the depletion gate 132) to an exit of the quantum dot qubit region 118 (i.e., a region beneath the depletion gate 134) before another carrier moves into the quantum dot qubit region 118. The accumulation gate 150 is disposed between the depletion gates 132 and 134 and covers the channel region 116.

The accumulation gates 150 are separated by barriers and cover the entirety of the quantum dot qubit region 118. In some embodiments, the accumulation gates 150 extend from above the source region 112 to above the drain region 114. However, the accumulation gates 150 do not cover portions of the depletion gates 132 and 134. In some embodiments, a high voltage is applied to each of the accumulation gates 150 during the operation to turn on the channel region 116 by inducing an inversion layer on the top surface of the channel region 116, so the accumulation gates 150 are designed to be thick enough to bear the high voltage. In some embodiments, the thickness of the accumulation gates 150 is in a range from about 30 nm to about 100 nm.

In some embodiments, a lateral distance between the conductive resonator and the accumulation gates 150 is in a range from about 15 nm to about 50 nm, such that the conductive resonator has a good control for the spin of qubits with low microwave source power, and the semiconductor device 100 is easy to be fabricated and has a dense package density. Further, with such range, the conductive resonator and the gates (i.e., the accumulation gate 150 and the depletion gates 132 and 134) still have good electrically isolation therebetween. If the lateral distance is less than about 15 nm, current leakage may occurs between the conductive resonator and the gates, thereby increasing noise and lowering controllability; if the lateral distance is greater than about 50 nm, the microwave source power may be increased, which may surpass the critical current of the conductive resonator and break superconductivity thereof.

The semiconductor device 100 generates qubits in the quantum dot qubit region 118 one at a time. During operation, an external magnetic field is applied to the quantum dot qubit region 118. A voltage is applied to the accumulation gates 150, which turn on the channel region 116. A current then flows from the source region 112, through the channel region 116, to the drain region 114. The depletion gates 132 and 134 are used to define the location of the quantum dot qubit region 118 and control the tunnel coupling between the source region 112 and the drain region 114. The controlled tunnel coupling allows only a single electron (or hole) passing through the quantum dot qubit region 118 before any other electron (or hole) moves into the quantum dot qubit region 118. The single electron passing through the quantum dot qubit region 118 is called a qubit. The conductive resonator is configured to generate microwave source.

In some embodiments, the accumulation gates 150 and/or the depletion gates 132 and 134 are conductive materials as the conductive resonator, including W, Ti, TiAlC, Al, TiAl, TaN, TaAlC, TiN, TiC, Co, TaC, Al, TiAl, HfTi, TiSi, TaSi, TiAlC, combinations thereof, or the like. In some embodiments, the accumulation gates 150, the depletion gates 132 and 134, and the conductive resonator are made of the same conductive materials, such that the accumulation gates 150, the depletion gates 132 and 134, and the conductive resonator have the same critical temperature and the same critical magnetic field. In some embodiments, the accumulation gates 150, the depletion gates 132 and 134, and the conductive resonator are made of different conductive materials. For example, the conductive resonator has a critical temperature (and/or a critical magnetic field) higher than that of the accumulation gates 150 (and/or the depletion gates 132 and 134).

In some embodiments, the substrate 110 and the channel region 116 are both of a first conductivity type, and the source region 112 and the drain region 114 are both of a second conductivity type opposite to the first conductivity type. For example, the substrate 110 is a p-type silicon substrate (p-substrate). P-type dopants may be introduced into the substrate 110 to form the p-substrate. The channel region 116 is a p-type region and has a dopant concentration greater than a dopant concentration of the substrate 110. The source region 112 and the drain region 114 are both n-type regions. In some other embodiments, both the substrate 110 and the channel region 116 are n-type, and both the source region 112 and the drain region 114 are p-type.

In some embodiments, the semiconductor device 100 further includes a source contact 136 and a drain contact 138 on the first side S1 of the substrate 110. The source contact 136 is connected to the source region 112 and forms an ohmic contact at the interface between the source contact 136 and the source region 112. Similarly, the drain contact 138 is connected to the drain region 114 and forms an ohmic contact at the interface between the drain contact 138 and the drain region 114. In some embodiments, the source contact 136 and the drain contact 138 are conductive materials as well.

In some embodiments, the semiconductor device 100 further includes another source contact 137 and another drain contact 139 on second side S2 of the substrate 110. The source contact 137 is connected to the source region 113 and forms an ohmic contact at the interface between the source contact 137 and the source region 113. Similarly, the drain contact 139 is connected to the drain region 115 and forms an ohmic contact at the interface between the drain contact 139 and the drain region 115. In some embodiments, the source contact 137 and the drain contact 139 are conductive materials as well.

In some embodiments, the semiconductor device 100 further includes a first dielectric layer 130 and a second dielectric layer 131. The first dielectric layer 130 is disposed on first side S1 of the substrate 110 and covers the source region 112, the drain region 114, the depletion gates 132 and 134, and the accumulation gates 150. As such, the first dielectric layer 130 provides good electrically isolation for the first quantum dot transistor structure 121 on the first side S1 of the substrate 110. The second dielectric layer 131 is disposed on second side S2 of the substrate 110 and covers the charge sensor. That is, the second dielectric layer 131 provides good electrical isolation for the second quantum dot transistor structure 122 on the second side S2 of the substrate 110.

In some embodiments, the first dielectric layer 130 and the second dielectric layer 131 may include silicon dioxide, silicon nitride, or other suitable material.

The second quantum dot transistor structure 122 on the second side S2 of the substrate 110 is, for example, used as a charge sensor. The charge sensor is used to read the quantum states of neighboring spin qubits. For example, when the semiconductor device 100 is operating, the accumulation gates 150 create a gate-induced charge layer in the channel region 116. Then, the depletion gates 132 and 134 form a tunnel barrier that interrupts the gate-induced charge layer with a single dopant implanted in the channel region 116. The depletion gates 132 and 134 also have the function of bringing the dopant level in resonance with the Fermi level of the leads. In the presence of a magnetic field, the Zeeman-split dopant states can also be resolved. By applying a source-drain bias and tuning the dopant level at resonance with the Fermi energies of the gate-induced charge layer, a sharp conductivity peak is expected to be observed. By inducing a Zeeman splitting of the electron or hole spin states with an external magnetic field, a spin-dependent tunneling may be observed. Because of charging effects, the resonant charge tunneling is sequential, that is, only one charge at a time can traverse the barrier by passing through the dopant level. The coherent manipulation of the quantum state of a spin qubit may use the application of magnetic fields, with a frequency matching the Zeeman splitting of the spin states. The frequency is determined by the impedance matching element mentioned above. In some embodiments, the magnetic field oscillates at microwave frequency to excite spin resonance of a single electron (dopant), i.e., electron spin resonance (ESR).

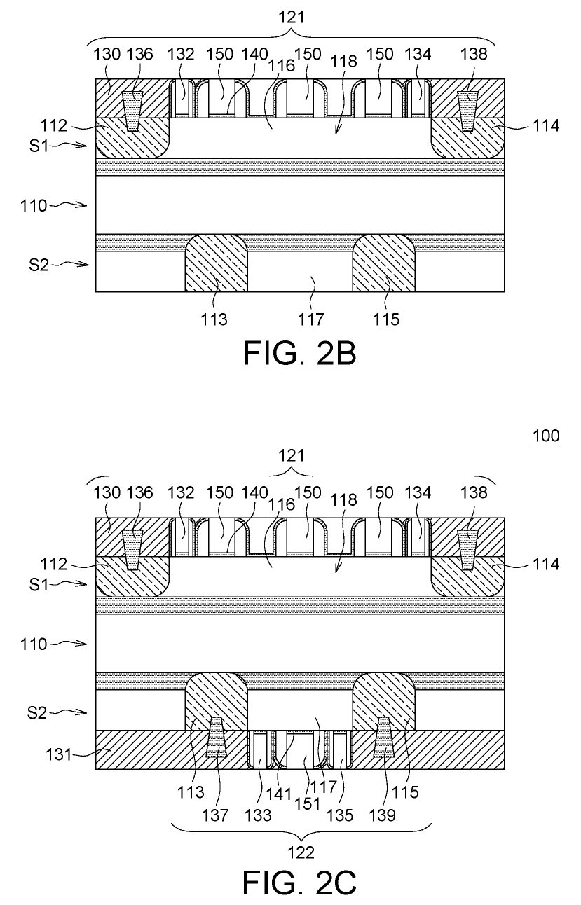

Referring to FIGS. 2A - 2C, the flows for manufacturing a semiconductor device are as follows. First, a substrate 110 is provided. In some embodiments, the substrate 110 includes silicon (Si). Alternatively, the substrate 110 may include germanium (Ge), silicon germanium (SiGe), gallium arsenide (GaAs), or other appropriate semiconductor materials. In some alternative embodiments, the substrate 110 includes an epitaxial layer with or without dopants. Furthermore, the substrate 110 may include a semiconductor-on-insulator (SOI) structure having a buried dielectric layer therein. In some embodiments, the substrate 110 includes a p-type silicon substrate (p-substrate) or n-type silicon substrate (n-substrate).

Referring to FIG. 2A, the substrate 110 may include an epitaxial structure composed of silicon (Si) and silicon germanium (SiGe) stacked to each other. For example, the uppermost and lowermost layers are SiGe, and three SiGe layers and two silicon layers are interlaced to form the substrate 110. The first quantum dot transistor structure 121 and the second quantum dot transistor structure 122 are respectively formed on two opposite surfaces (i.e., SiGe layers) of the substrate 110 in subsequent processes.

As shown in FIG. 2A, an implantation process is performed to introduce first impurities into a first side of the substrate 110 to form a channel region 116 in the first side S1 of the substrate 110. The first impurities may be p-type impurities or n-type impurities. The n-type impurities may be phosphorus, arsenic, or the like, and the p-type impurities may be boron, BF₂, or the like. For example, the channel region 116 is a p-type region formed in the p-substrate.

Another implantation process is then performed to introduce second impurities into the well region to form a source region 112 and a drain region 114. The second impurities may be n-type impurities or p-type impurities. The n-type impurities may be phosphorus, arsenic, or the like, and the p-type impurities may be boron, BF₂, or the like. For example, the source region 112 and the drain region 114 are n-type regions formed in the p-type well region, such that the channel region 116 is formed between the source region 112 and the drain region 114.

Next, a first gate dielectric layer 140 and a first conductive layer (i.e., 132, 134, 150) are sequentially formed over the channel region 116 in FIG. 2B. In some embodiments, the first gate dielectric layer 140 includes silicon dioxide, silicon nitride, or other suitable material. Alternatively, the first gate dielectric layer 140 can be a high-κ dielectric layer having a dielectric constant (κ) higher than the dielectric constant of SiO2, i.e. κ>3.9. The first gate dielectric layer 140 may include LaO, AlO, ZrO, TiO, Ta₂O₅, Y2O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, Si₃N₄, oxynitrides (SiON), or other suitable materials. The first gate dielectric layer 140 is deposited by suitable techniques, such as ALD, CVD, PVD, thermal oxidation, combinations thereof, or other suitable techniques.

The first conductive layer (i.e., 132, 134, 150) is formed over the first gate dielectric layer 140. The first conductive layer may be formed by physical vapor deposition (PVD) including sputtering, chemical vapor deposition (CVD), atomic layer deposition (ALD) or other suitable method.

The first conductive layer (i.e., 132, 134, 150) is patterned, by using the patterned photoresist layer as an etch mask, to form a pair of depletion gates 132, 134 and the accumulation gates 150. The patterning of the first conductive layer may be performed by using an etching process. In some embodiments, the etching process is a dry etching process with etching gases CF₄, SF₆, combinations thereof, or the like. After the etching process, the patterned photoresist layer is removed, and the removal method may be performed by solvent stripping or plasma ashing, for example. The pair of the depletion gates 132 and 134 is formed between the source region 112 and the drain region 114. For example, the depletion gate 132 partially covers the source region 112, and the depletion gate 134 partially covers the drain region 114. The pair of the depletion gates 132 and 134 is spaced apart from each other.

In some embodiments, the source region 112, the drain region 114, the channel region 116, the depletion gates 132 and 134 and the accumulation gates 150 form a first quantum dot transistor structure 121 on the first side S1 of the substrate 110. The quantum dot qubit region 118 is arranged in a one-dimensional or two-dimensional array, such as a 6x6 qubit array or other arrangements.

Next, a first dielectric layer 130 is formed over the substrate 110 and covers the first quantum dot transistor structure 121. Further, the first dielectric layer 130 may be formed of a material that includes an oxide material, such as, silicon oxide, silicon nitride, or the like.

In addition, as shown in FIG. 2A, an implantation process is performed on a second side S2 of the substrate 110 to form another source region 113, another drain region 115 and another channel region 117 in the second side S2 of the substrate 110. The processes for forming the source region 113, the drain region 115 and the channel region 117 are the same as the processes described above for forming the source region 112, the drain region 114 and the channel region 116.

Next, as shown in FIG. 2C, a second gate dielectric layer 141 and a second conductive layer (i.e., 133, 135, 151) are sequentially formed over the channel region 117. In some embodiments, the second gate dielectric layer 141 and the first gate dielectric layer 140 may be made of the same material, and the second conductive layer and the first conductive layer may be made of the same material, as described above. Afterwards, the second conductive layer (i.e., 133, 135, 151) is patterned by using a patterned photoresist layer (not shown) as an etching mask to form another pair of depletion gates 133, 135 and an accumulation gate 151, as same as the processes described above for forming the pair of depletion gates 132, 134 and the accumulation gates 150. Then, the second dielectric layer 131 directly forms over the substrate 110 and covers the second quantum dot transistor structure 122. That is, the source region 113, the drain region 115, the channel region 117, the depletion gates 133 and 135 and the accumulation gate 151 form a charge sensor on the second side S2 of the substrate 110. The charge sensors are arranged in a one-dimensional or two-dimensional array, such as a 2x2 arrangement or other arrangements. In some embodiments, each charge sensor can be used to read electron or hole spin states in two, three, or more qubits in quantum dot qubit region 118 at the top of the charge sensor, but is not limited thereto.

It is important to accurately read the state of a qubit at any given time in a quantum processing device. Therefore, the charge sensors are integrated into the semiconductor device 100 and adjacent to the quantum dots to obtain two, three or more qubits are necessary. The charge sensor may be a single-electron field-effect transistor (SET), which has the advantages of low power consumption and high-density assembly. If used in conjunction with today's field-effect transistors, an integrated circuit with high speed, low power consumption, and high component density can be achieved. For future development of complex and scalable quantum computers including hundreds, thousands or millions of qubits, components with charge sensors of the smallest possible footprint are desired to minimize the size of the semiconductor device 100.

Spin readout is an important requirement for fault-tolerant quantum computing in spin qubits. Spin readout can be performed using a single-shot spin readout, which means that the spin state can be determined using a single iteration of the readout sequence. Single-shot readout is necessary for quantum error correction and readout at the end of the calculation, and must be performed with high reliability and precision. In some embodiments, for a single-shot readout of spin-to-charge conversion in single, dual and triple quantum dot qubits, arrays of three or more charge sensors are used to sensitively detect charge spins. In some embodiments, three or more charge sensors provide good coverage of the entire quantum dot array to read the spin states of the nine or more qubits.

To overcome some of these problems, such as the footprint of the charge sensors, a two-dimensional array of quantum dots is disposed on one side of the substrate 110 and a two-dimensional array of the charge sensors is disposed on the other side of the substrate 110 to reduce the device complexity and geometric footprint required to perform spin readout. In contrast to qubits and charge sensors being disposed on the same side of the substrate, this type of charge sensor array and quantum dot array vertically configured in the substrate can integrate the qubit readout capability into the existing control architecture of the semiconductor device 100. Therefore, the footprint occupied by additional near-end charge sensors in the semiconductor device 100 can be reduced.

The present disclosure provides a one-dimensional or two-dimensional array of quantum dots on one side of the substrate and a one-dimensional or two-dimensional array of charge sensors on the other side of the substrate to reduce the device complexity and geometric footprint required to perform spin readout. The quantum dots are used to host the spin states of quantum dot qubits in the quantum dot transistor structure, and the charge sensors are used for spin readout of quantum dot qubits in the quantum dot transistor structure. Therefore, the footprint occupied by additional near-end charge sensors in the semiconductor device can be reduced.

According to some embodiments of the present disclosure, a semiconductor device includes a substrate, a first quantum dot transistor structure and a second quantum dot transistor structure. The substrate has a first side and a second side opposite to the first side. The first quantum dot transistor structure is disposed on the first side. The second quantum dot transistor structure is disposed on the second side for spin readout of a plurality of quantum dot qubits in the first quantum dot transistor structure.

According to some embodiments of the present disclosure, a semiconductor device includes a substrate, a first quantum dot transistor structure and a second quantum dot transistor structure. The substrate has a first side and a second side opposite to the first side. The first quantum dot transistor structure is disposed on the first side. The first quantum dot transistor structure includes a pair of depletion gates and a plurality of accumulation gates, wherein the plurality of accumulation gates is disposed between the pair of depletion gates. The second quantum dot transistor structure is disposed on the second side for spin readout of a plurality of quantum dot qubits in the first quantum dot transistor structure.

According to some embodiments of the present disclosure, a method for manufacturing a semiconductor device is provided with the following steps. A channel region, a source region and a drain region is formed in a first side of a substrate. A first gate dielectric layer and a first conductive layer are deposited over the substrate to cover the channel region. The first gate dielectric layer and the first conductive layer are patterned to form a pair of depletion gates crossing the channel region and a plurality of accumulation gates between the pair of the depletion gates. Another channel region, another source region and another drain region are formed in a second side of the substrate, and the second side is opposite to the first side. A second gate dielectric layer and a second conductive layer is deposited over the second side of the substrate to cover the another channel region. The second gate dielectric layer and the second conductive layer are patterned to form another pair of depletion gates crossing the another channel region and at least another accumulation gate between the another pair of the depletion gates.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate having a first side and a second side opposite to the first side;
a first quantum dot transistor structure disposed on the first side; and
a second quantum dot transistor structure disposed on the second side for spin readout of a plurality of quantum dot qubits in the first quantum dot transistor structure.

2. The semiconductor device of claim 1, wherein the plurality of quantum dot qubits is arranged in a one-dimensional or two-dimensional array.

3. The semiconductor device of claim 1, wherein the second quantum dot transistor structure comprises at least one charge sensor, and the charge sensor is used to read electron or hole spin states in the plurality of quantum dot qubits.

4. The semiconductor device of claim 3, wherein the charge sensor is a single-electron field-effect transistor.

5. The semiconductor device of claim 1, wherein the second quantum dot transistor structure comprises a plurality of charge sensors arranged in a one-dimensional or two-dimensional array.

6. The semiconductor device of claim 1, wherein the substrate comprises an epitaxial structure composed of silicon (Si) and silicon germanium (SiGe) stacked to each other.

7. A semiconductor device, comprising:
a substrate having a first side and a second side opposite to the first side;
a first quantum dot transistor structure disposed on the first side, comprising a pair of depletion gates and a plurality of accumulation gates, wherein the plurality of accumulation gates is disposed between the pair of depletion gates; and
a second quantum dot transistor structure disposed on the second side for spin readout of a plurality of quantum dot qubits in the first quantum dot transistor structure.

8. The semiconductor device of claim 7, wherein the plurality of quantum dot qubits is arranged in a one-dimensional or two-dimensional array.

9. The semiconductor device of claim 7, wherein the second quantum dot transistor structure comprises at least one charge sensor, and the charge sensor is used to read electron or hole spin states in the plurality of quantum dot qubits.

10. The semiconductor device of claim 9, wherein the charge sensor is a single-electron field-effect transistor.

11. The semiconductor device of claim 7, wherein the second quantum dot transistor structure comprises a plurality of charge sensors arranged in a one-dimensional or two-dimensional array.

12. The semiconductor device of claim 7, wherein the substrate comprises an epitaxial structure composed of silicon (Si) and silicon germanium (SiGe) stacked to each other.

13. A method for manufacturing a semiconductor device, comprising:
forming a channel region, a source region and a drain region in a first side of a substrate;
depositing a first gate dielectric layer and a first conductive layer over the substrate to cover the channel region;
patterning the first gate dielectric layer and the first conductive layer to form a pair of depletion gates crossing the channel region and a plurality of accumulation gates between the pair of the depletion gates; and
forming another channel region, another source region and another drain region in a second side of the substrate, the second side being opposite to the first side;
depositing a second gate dielectric layer and a second conductive layer over the second side of the substrate to cover the another channel region; and
patterning the second gate dielectric layer and the second conductive layer to form another pair of depletion gates crossing the another channel region and at least another accumulation gate between the another pair of the depletion gates.

14. The method for manufacturing a semiconductor device of claim 13, wherein the source region, the drain region, the channel region, the pair of depletion gates and the plurality of accumulation gates form a first quantum dot transistor structure on the first side of the substrate.

15. The method for manufacturing a semiconductor device of claim 14, wherein the another source region, the another drain region, the another channel region, the another pair of depletion gates and the at least one another accumulation gate form a second quantum dot transistor structure on the second side of the substrate.

16. The method for manufacturing a semiconductor device of claim 15, wherein the second quantum dot transistor structure is used for spin readout of a plurality of quantum dot qubits in the first quantum dot transistor structure.

17. The method for manufacturing a semiconductor device of claim 16, wherein the plurality of quantum dot qubits is arranged in a one-dimensional or two-dimensional array.

18. The method for manufacturing a semiconductor device of claim 16, wherein the second quantum dot transistor structure comprises at least one charge sensor, and the charge sensor is used to read electron or hole spin states in the plurality of quantum dot qubits.

19. The method for manufacturing a semiconductor device of claim 18, wherein the charge sensor is a single-electron field-effect transistor.

20. The method for manufacturing a semiconductor device of claim 13, wherein the substrate comprises an epitaxial structure composed of silicon (Si) and silicon germanium (SiGe) stacked to each other.
